(19) United States
(12) Patent Application Publication
(10) Pub. No.: US 2016/0166868 A1
(43) Pub. Date: Jun. 16, 2016

(54) PLASMA ABATEMENT USING WATER VAPOR IN CONJUNCTION WITH HYDROGEN OR HYDROGEN CONTAINING GASES

(71) Applicant: Applied Materials, Inc., Santa Clara, CA (US)

(72) Inventor: Colin John DICKINSON, San Jose, CA (US)

(21) Appl. No.: 14/944,030

(22) Filed: Nov. 17, 2015

Related U.S. Application Data
(60) Provisional application No. 62/135,449, filed on Mar. 19, 2015.
(60) Provisional application No. 62/092,581, filed on Dec. 16, 2014.

(51) Int. Cl. A62D 3/30; H01J 37/32

(52) U.S. Cl. CPC A62D 3/30; H01J 37/32844; A62D 2101/22

(57) ABSTRACT

A plasma abatement process for abating effluent containing a PFC gas from a processing chamber is described. A plasma abatement process takes gaseous foreline effluent from a processing chamber, such as an etch chamber, and reacts with the effluent within a plasma chamber placed in the foreline path. The plasma dissociates the PFC gases and reacts them with a reagent, converting the effluent into compounds that are non-global warming and which may be easily removed by traditional facility water scrubbing technology. This disclosure explains methods to control the reagent hydrogen to oxygen ratio such that in addition to PFC destruction, the abated compounds have modified composition to enable extension of the maintenance interval for downstream supporting equipment.

### CROSS-REFERENCE TO RELATED APPLICATIONS

This application claims benefit of U.S. Provisional Patent Application Ser. No. 62/092,581 (APPM/22539USL), filed Dec. 16, 2014, and of U.S. Provisional Patent Application Ser. No. 62/135,449 (APPM/22539USL02), filed Mar. 19, 2015, which are herein incorporated by reference.

### BACKGROUND

1. Field

Implementations of the present disclosure generally relate to abatement for semiconductor processing equipment. More particularly, implementations of the present disclosure relate to techniques for abating compounds present in the effluent.

2. Description of the Related Art

Effluent produced during semiconductor manufacturing processes includes many compounds which must be abated or treated before disposal, due to regulatory requirements and environmental and safety concerns. Among these compounds are perfluorocarbons (PFCs), which are used, for example, in etching processes.

PFCs, such as CF₄, C₂F₆, NF₃ and SF₆, are commonly used in the semiconductor and flat panel display manufacturing industries, for example, in dielectric layer etching and chamber cleaning. Following the manufacturing or cleaning process there is typically a residual PFC content in the effluent gas stream pumped from the process tool. PFCs are difficult to remove from the effluent stream, and their release into the environment is undesirable because they are known to have relatively high greenhouse activity. Remote plasma sources (RPS) or in-line plasma sources (IPS) have been used for abatement of PFCs and global warming gases.

The design of current abatement technology for abating PFC's utilizes either water vapor, as a source of hydrogen and oxygen as a reagent or oxygen only. These provide excellent destruction capability for PFC gases, but it has been identified that further improvements may be made that also have additional benefit of maintaining cleanliness and reliability of downstream vacuum equipment for extending interval between maintenance.

### SUMMARY

Implementations disclosed herein include method and systems of abating effluent from a processing chamber. These include methods to specifically control the ratio of hydrogen to oxygen reagent composition to maintain effective PFC abatement performance and also enable improvements to support equipment maintenance interval.

In one implementation, a method of processing effluent can include flowing an effluent from a processing chamber into a plasma source, wherein the effluent comprises a PFC gas; delivering an abating reagent to the plasma source, the abating reagent comprising a hydrogen to oxygen ratio of at least 2.5:1; and activating the effluent and the abating reagent in the presence of a plasma to convert the PFC gas to an abated material.

In another implementation, a method for abating an effluent gas can include flowing an abating reagent into a plasma chamber; flowing an effluent gas into the plasma chamber, the effluent gas comprising a PFC gas such that the gas to be abated reacts with the plasma, wherein the hydrogen to halogen ratio is about 1:1 and the oxygen to PFC gas ratio is about 2:1; and generating a plasma in the plasma chamber from the abating reagent.

In another implementation, a method of processing effluent can include flowing an effluent comprising PFC gas from a processing chamber into a plasma source; delivering an abating reagent to the plasma source, the abating reagent comprising H₂ and H₂O, the H₂ and H₂O being delivered at a hydrogen to oxygen ratio of at least 3:1, wherein the H₂ is formed by H₂O electrolysis; and forming an inductively coupled plasma from the effluent and the abating reagent creating an abated material, wherein the abated material is gaseous at operating temperatures and pressures.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 depicts a schematic diagram of a substrate processing system in accordance with some implementations.

FIG. 2 is a flow diagram illustrating one implementation of a method for abating effluent exiting a processing chamber.

To facilitate understanding, identical reference numerals have been used, wherever possible, to designate identical elements that are common to the Figures. Additionally, elements of one implementation may be advantageously adapted for utilization in other implementations described herein.

### DETAILED DESCRIPTION

Implementations disclosed herein include a plasma abatement process for materials present in an effluent exiting a processing chamber. A plasma abatement process takes foreline effluent from a processing chamber, such as a deposition chamber, an etch chamber or other vacuum processing chamber, and reacts the effluent with an abating reagent within a plasma chamber placed in the foreline path. The plasma energizes the materials present in the effluent as well as the abating reagent, making conversion of the material into a more benign form more efficient. In some implementations, the plasma may at least partially dissociate the materials present within the effluent and the abating reagent, which increases the efficiency of the conversion of the materials within the effluent into more benign forms. An abating reagent, such as water, may assist in the abating of the materials present within the effluent.

In implementations described herein, excess hydrogen can be added to the water vapor in the abating reagent, creating a hydrogen to oxygen ratio of at least 2.5:1. The addition of hydrogen to the water vapor maintains the inherent safety of water vapor addition while controlling reactive oxygen available after reaction with effluent perfluorocompounds (PFC) gases. In methods and systems described herein, hydrogen generation by electrolysis of deionized water may be employed. Implementations disclosed herein are more clearly described with reference to the figures below.

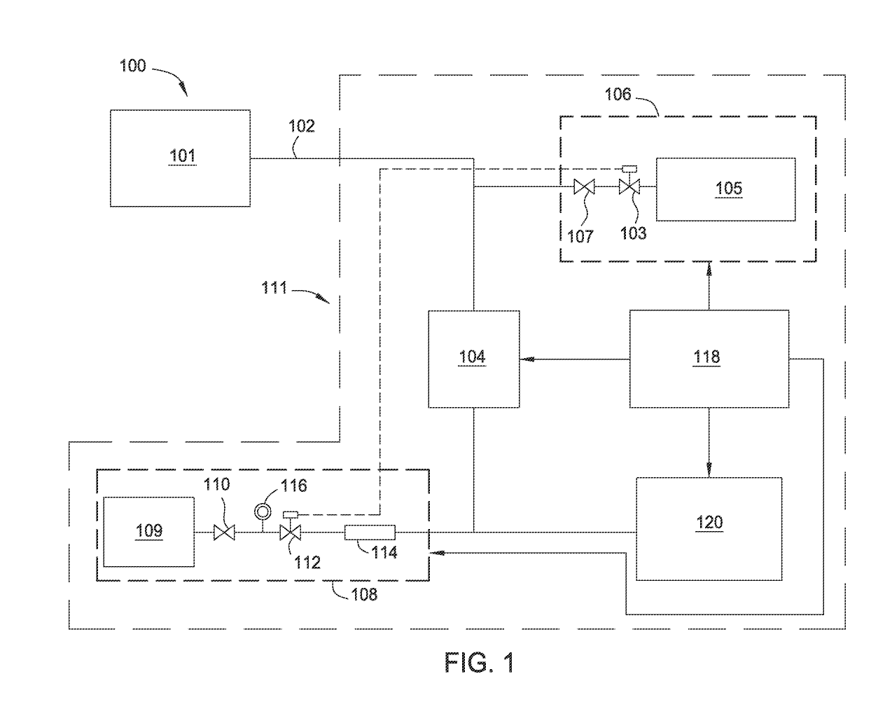

FIG. 1 depicts a schematic diagram of a processing system 100 in accordance with the implementations disclosed herein. As shown in FIG. 1, a foreline 102 couples a processing chamber 101 with an abatement system 111. The processing chamber 101 may be, for example, a processing chamber for carrying out a deposition process, an etching process, annealing or a cleaning process, among others. Representative chambers for carrying out a deposition process include deposition chambers, such as, for example, plasma enhanced chemical vapor deposition (PECVD) chambers, chemical vapor deposition (CVD) chambers, or physical vapor deposition (PVD) chambers. In some implementations, the deposition process may be one that deposits dielectrics, such as silicon dioxide, (SiO₂), silicon nitride (SiNₓ), silicon oxynitride (SiON), crystalline silicon, a-Si, doped a-Si, fluorinated glass (FSG), phosphorous doped glass (PSG), boron-phosphorous doped glass (BPSG), carbon-doped glass, and other low-k dielectrics, such as polyimides and organosiloxanes. In other implementations, the deposition process may be one that deposits metals, metal oxides, or metal nitrides, such as, for example, titanium, titanium dioxide, tungsten, tungsten nitride, tantalum, tantalum nitride, tantalum carbide, aluminum, aluminum oxide, aluminum nitride, ruthenium, or cobalt. In addition, metal alloys may be deposited, such as lithium-phosphorous-oxynitride, lithium-cobalt, and many others.

Foreline 102 serves as a conduit that routes effluent leaving the processing chamber 101 to the abatement system 111. The effluent may contain material which is undesirable for release into the atmosphere or may damage downstream equipment, such as vacuum pumps. For example, the effluent may contain compounds from a dielectric deposition process or from a metal deposition process.

Examples of silicon-containing materials which may be present in the effluent include, for example, silicon dioxide (SiO₂), silane (SiH₄), disilane, silicon tetrachloride (SiCl₄), silicon nitride (SiNₓ), dichlorosilane (SiH₂Cl₂), hexachlorodisilane (Si₂Cl₆), bis(t-butyl amino)silane, trisilylamine, disilylmethane, trisilylmethane, tetrasilylmethane, and tetraethyl orthosilicate (TEOS) (Si(OEt)₄). Other examples of silicon-containing materials include disiloxanes, such as disiloxane (SiH₃OSiH₃), trisiloxane (SiH₃OSiH₂OSiH₃), tetrasiloxane (SiH₃OSiH₂OSiH₂OSiH₃), and cyclotrisiloxane (—SiH₂OSiH₂OSiH₂O—). Examples of other materials which may be present in the effluent include stibine (SbH₃), germane (GH₄), hydrogen telluride, and carbon-containing compounds, such as CH₄ and higher order alkanes.

One abatement system 111 that may be modified to benefit from the implementation is a ZFP2™ abatement system available from Applied Materials, located in Santa Clara, Calif., among other suitable systems. As shown, the abatement system 111 includes a plasma source 104, a reagent delivery system 106, a foreline gas injection kit 108, a controller 118, and a vacuum source 120. Foreline 102 provides effluent leaving the processing chamber 101 to the plasma source 104. The plasma source 104 may be any plasma source coupled to the foreline 102 suitable for generating a plasma therein. For example, the plasma source 104 may be a remote plasma source, an in-line plasma source, or other suitable plasma source for generating a plasma within the foreline 102 or proximate the foreline 102 for introducing reactive species into the foreline 102. The plasma source 104 may be, for example, an inductively coupled plasma source, a capacitively coupled plasma source, a direct current plasma source, or a microwave plasma source. The plasma source 104 may further be a magnetically enhanced plasma source of any kind described above.

A reagent delivery system 106 may also be coupled with the foreline 102. The reagent delivery system 106 delivers one or more reagents, such as abating reagents, to the foreline 102 upstream of the plasma source 104. In an alternative implementation, the reagent delivery system 106 may be coupled directly to the plasma source 104 for delivering reagents directly into the plasma source 104. The reagent delivery system 106 may include a reagent source 105 (or multiple reagent sources (not shown)) coupled to the foreline 102 (or the plasma source 104) via one or more valves. For example, in some implementations, a valve scheme may include a two-way control valve 103, which functions as an on/off switch for controlling the flow the one or more reagents from the reagent source 105 into the foreline 102, and a flow control device 107, which controls the flow rates of the one or more reagents into the foreline 102. The flow control device 107 may be disposed between the foreline 102 and the control valve 103. The control valve 103 may be any suitable control valve, such as a solenoid valve, pneumatic valve or the like. The flow control device 107 may be any suitable active or passive flow control device, such as a fixed orifice, mass flow controller, needle valve or the like.

A representative volatizing abating reagent that may be delivered by the reagent delivery system 106 includes, for example, H₂O. H₂O may be used when abating effluent containing, for example, CF₄ and/or other materials. A hydrogen-containing gas may be used in conjunction with H₂O in one or more implementations. Representative hydrogen-containing gases includes ammonia (NH₃) and H₂. In some implementations, the volatilizing abating reagents may be consumed by the compounds of the effluent, and therefore, may not be considered catalytic.

A foreline gas injection kit 108 may also be coupled to the foreline 102 upstream or downstream of the plasma source 104 (downstream depicted in FIG. 1). The foreline gas injection kit 108 may controllably provide a foreline gas, such as nitrogen (N₂), argon (Ar), or clean dry air, into the foreline 102 to control the pressure within the foreline 102. The foreline gas injection kit 108 may include a foreline gas source 109 followed by a pressure regulator 110, further followed by a control valve 112, and even further followed by a flow control device 114. The pressure regulator 110 sets the gas delivery pressure set point. The control valve 112 turns on and off the gas flow. The control valve 112 may be any suitable control valve, such as discussed above for control valve 103. The flow control device 114 provides the flow of gas specified by the set point of pressure regulator 110. The flow control device 114 may be any suitable flow control device, such as discussed above for flow control device 107.

In some implementations the foreline gas injection kit 108 may further include a pressure gauge 116. The pressure gauge 116 may be disposed between the pressure regulator 110 and the flow control device 114. The pressure gauge 116 may be used to measure pressure in the kit 108 upstream of the flow control device 114. The measured pressure at the pressure gauge 116 may be utilized by a control device, such as a controller 118, discussed below, to set the pressure upstream of the flow control device 114 by controlling the pressure regulator 110.

In some implementations, the control valve 112 may be controlled by the controller 118 to only turn gas on when the reagent from the reagent delivery system 106 is flowing, such that usage of gas is minimized. For example, as illustrated by the dotted line between control valve 103 of the reagent delivery system 106 and the control valve 112 of the kit 108, the control valve 112 may turn on (or off) in response to the control valve 103 being turned on (or off).

The foreline 102 may be coupled to a vacuum source 120 or other suitable pumping apparatus. The vacuum source 120 pumps the effluent from the processing chamber 101 to appropriate downstream effluent handling equipment, such as to a scrubber, incinerator or the like. In some implementations, the vacuum source 120 may be a backing pump, such as a dry mechanical pump or the like. The vacuum source 120 may have a variable pumping capacity with can be set at a desired level, for example, to control or provide additional control of pressure in the foreline 102.

The controller 118 may be coupled to various components of the substrate processing system 100 to control the operation thereof. For example, the controller may monitor and/or control the foreline gas injection kit 108, the reagent delivery system 106, and/or the plasma source 104 in accordance with the teachings disclosed herein.

The implementations of FIG. 1 are schematically represented and some components have been omitted for simplicity. For example, a high speed vacuum pump, such as a turbo molecular pump or the like, may be disposed between the processing chamber 101 and the foreline 102 for removing effluent gases from the processing chamber 101. Additionally, other variants of components may be provided to supply the foreline gas, the reagent, and/or the plasma.

In an exemplary implementation of the method disclosed herein, effluent containing undesirable material exiting from the processing chamber 101 enters the plasma source 104. The effluent can include a PFC gas which can be a carbon-containing gas, a nitrogen containing gas or a sulfur containing gas. In one implementation, the PFC is a gas selected from the group comprising or consisting of CF₄, CH₃F, CH₂F₂, CH₄, C₂F₆, C₃F₈, C₄F₁₀, CHF₃, SF₆, and NF₃. Combinations of the above described PFC gases may be present in the effluent. An abating reagent with a hydrogen to oxygen ratio of at least a 2.5:1, such as a water vapor and hydrogen containing gas, enters the plasma source 104. A plasma is generated from the abating reagent within the plasma source 104, thereby energizing the abating reagent, and in some implementations, also energizing the effluent. In some implementations, at least some of the abating reagent and/or material entrained in the effluent are at least partially disassociated. The identity of the abating reagent, the flow rate of the abating reagent, the foreline gas injection parameters, and the plasma generation conditions may be determined based on the composition of the material entrained in the effluent and may be controlled by the controller 118. In an implementation where the plasma source 104 is an inductively coupled plasma source, dissociation may require several kW of power.

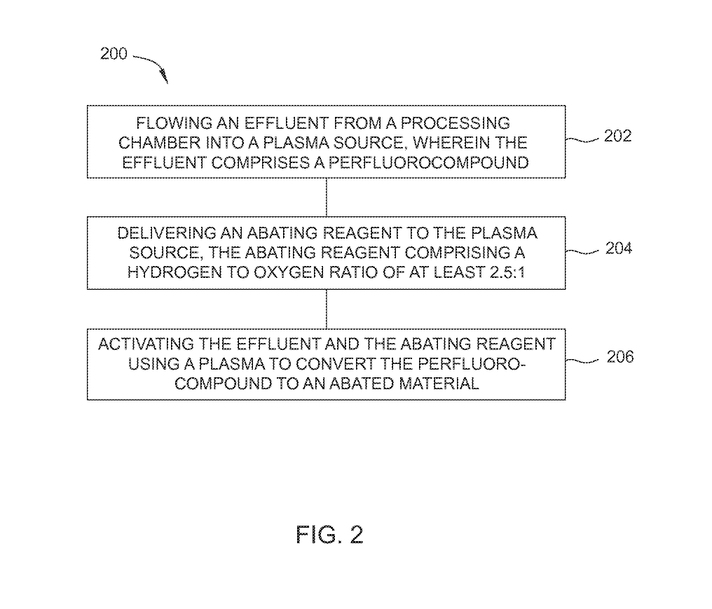

FIG. 2 is a flow diagram illustrating one implementation of a volatilizing method 200 for abating a target material in an effluent exiting a processing chamber. The method 200 begins by flowing an effluent from a processing chamber, such as processing chamber 101, into a plasma source, such as plasma source 104, wherein the effluent comprises a PFC, at 202; delivering an abating reagent to the plasma source, the abating reagent comprising a hydrogen to oxygen ratio of at least 2.5:1, at 204; and activating the effluent and the abating reagent in the presence of a plasma to convert the PFC in the effluent and the abating reagent to an abated material, at 306. In some implementations, at least some of the abating reagent and/or material entrained in the effluent are at least partially disassociated. The target material in the effluent is converted to an abated material in the presence of the plasma including the abating reagent formed in the plasma source. The material in the effluent may then exit the plasma source and flow into the vacuum source, such as vacuum source 120, and/or be further treated.

The method 200 begins by flowing an effluent from a processing chamber into a plasma source, wherein the effluent comprises a PFC, at 202. Effluent containing materials desired for abatement, such as PFC compounds, is flowed into the plasma source 104. In one example, the exhaust gas may have originated at the process chamber 101 and resulted from performing any of a number of processes, such as etching, deposition, cleaning, or the like. The reagent gas may be injected into the foreline 102, for example, by the reagent delivery system 106.

An abating reagent can be delivered to the plasma source, at 204. In a representative abatement process using H₂O, H₂O from the reagent delivery system 106 is flowed into the plasma source 104. The H₂O can be delivered with a hydrogen containing reagent. Hydrogen containing reagents can include H₂, ammonia (NH₃), methane (CH₄) or combinations thereof. In one implementation, H₂ is delivered simultaneously with H₂O. The abating reagent has a hydrogen to oxygen ratio of at least 2.5:1, such as a hydrogen to oxygen ratio of at least 3:1. In one implementation, the hydrogen to oxygen ratio is from about 3:1 to about 10:1. In another implementation, the abating reagent includes at least one of H₂, H₂O, ammonia, or methane. The abating reagent can further include combinations of gases to achieve the desired hydrogen to oxygen ratio.

The effluent and the abating reagent can be activated using a plasma to convert the PFC gas to an abated material, at 206. A plasma is generated within the plasma source 104, and thereby converting the PFC compounds into hydrogen halide compounds and oxide compounds. The hydrogen halide compounds and oxide compounds are volatile and more benign to human health and downstream effluent handling components than the unabated effluent. The plasma can be generated using plasma generation methods known in the art, such as microwave plasma, inductively coupled plasma or capacitively coupled plasma. In one implementation, the plasma is inductively coupled plasma. The resulting abated material will be gaseous at operating temperatures and pressures.

The previously described implementations have many advantages. For example, the techniques disclosed herein can convert volatile, toxic, and/or explosive effluent into much more benign chemicals that can be more safely handled. The plasma abatement process is beneficial to human health in terms of acute exposure to the effluent by workers and by conversion of pyrophoric or toxic materials into more environmentally friendly and stable materials. The plasma abatement process also protects semiconductor processing equipment, such as, for example, vacuum pumps, from excessive wear and premature failure by removing particulates and/or other corrosive materials from the effluent stream. Moreover, performing the abatement technique on the vacuum foreline adds additional safety to workers and equipment. If an equipment leak occurs during the abatement process, the low pressure of the effluent relative to the outside environment prevents the effluent from escaping the abatement equipment. Additionally, many of the abating reagents disclosed herein are low-cost and versatile. For example, H₂O and H₂, as used in the abatement of PFC gases, are both versatile and low-cost. The aforementioned advantages are illustrative and not limiting. It is not necessary for all implementations to have all the advantages.

While the foregoing is directed to implementations of the disclosed devices, methods and systems, other and further implementations of the disclosed devices, methods and systems may be devised without departing from the basic scope thereof, and the scope thereof is determined by the claims that follow.

What is claimed is:

1. A method of processing effluent comprising:
flowing an effluent from a processing chamber into a plasma source, wherein the effluent comprises a PFC gas;
delivering a combination of abating reagents to the plasma source, the abating reagent comprising a hydrogen to oxygen ratio of at least 2.5:1; and
activating the effluent and the abating reagent in the presence of a plasma to convert the PFC gas to an abated material.

2. The method of claim 1, wherein the PFC gas is a carbon-containing gas, a nitrogen-containing gas or a sulfur-containing gas.

3. The method of claim 1, wherein the abating reagent comprises at least one of H₂, H₂O, ammonia, or methane.

4. The method of claim 1, wherein the plasma is an inductively coupled plasma.

5. The method of claim 1, wherein the hydrogen to oxygen ratio is from about 3:1 to about 10:1

6. The method of claim 1, wherein the abating reagent comprises H₂ and the H₂ is delivered from a H₂O electrolysis system.

7. The method of claim 1, wherein the PFC gas is a gas selected from the group comprising or consisting of CF₄, C₂ F₆, C₃F₈, C₄F₁₀, CHF₃, SF₆, NF₃, CH₃F, and CH₂F₂.

8. The method of claim 1, wherein the abating reagent and the effluent are combined prior to forming a plasma.

9. A method for abating an effluent gas, the method comprising:
flowing an abating reagent into a plasma chamber;
flowing an effluent gas into the plasma chamber, the effluent gas comprising a PFC gas such that the gas to be abated reacts with the plasma, wherein the hydrogen to halogen ratio is about 1:1 and the oxygen to carbon or sulfur ratio is about 2:1; and
generating a plasma in the plasma chamber from the abating reagent.

10. The method of claim 9, wherein the PFC gas is a carbon-containing gas, a nitrogen-containing gas or a sulfur-containing gas.

11. The method of claim 9, wherein the abating reagent comprises at least one of H₂, H₂O, ammonia, or methane.

12. The method of claim 9, wherein the plasma is an inductively coupled plasma.

13. The method of claim 9, wherein the hydrogen to oxygen ratio is from about 3:1 to about 10:1

14. The method of claim 9, wherein the abating reagent comprises H₂ and the H₂ is delivered from a H₂O electrolysis system.

15. The method of claim 9, wherein the abating reagent and the effluent are combined prior to forming a plasma.

16. The method of claim 9, wherein the PFC gas is a gas selected from the group comprising or consisting of CF₄, C₂ F₆, C₃F₈, C₄F₁₀, CHF₃, SF₆, NF₃, CH₃F, and CH₂F₂.

17. A method of processing effluent comprising:
flowing an effluent comprising a PFC gas from a processing chamber into a plasma source;
delivering an abating reagent to the plasma source, the abating reagent comprising H₂ and H₂O, the H₂ and H₂O being delivered at a hydrogen to oxygen ratio of at least 3:1, wherein the H₂ is formed by H₂O electrolysis; and
forming an inductively coupled plasma from the effluent and the abating reagent creating an abated material.

18. The method of claim 16, wherein the PFC gas is a carbon-containing gas, a nitrogen-containing gas or a sulfur-containing gas.

19. The method of claim 16, wherein the hydrogen to oxygen ratio is from about 3:1 to about 10:1.

20. The method of claim 16, wherein the PFC gas is a gas selected from the group comprising or consisting of CF₄, C₂ F₆, C₃F₈, C₄F₁₀, CHF₃, SF₆, NF₃, CH₃F, and CH₂F₂.
